(19) United States
(12) Patent Application Publication
(10) Pub. No.: US 2024/0397702 A1
(43) Pub. Date: Nov. 28, 2024

(54) SEMICONDUCTOR MEMORY DEVICE AND METHOD FOR FABRICATING THE SAME

(71) Applicant: Samsung Electronics Co., Ltd., Suwon-si (KR)

(72) Inventors: Sung Hoon BAE, Suwon-si (KR); Han Seong SHIN, Suwon-si (KR); Tae Young EOM, Suwon-si (KR)

(21) Appl. No.: 18/659,483

(22) Filed: May 9, 2024

(30) Foreign Application Priority Data
May 24, 2023 (KR) 10-2023-0066859

(51) Int. Cl. H10B 12/00; H01L 23/528

(52) U.S. Cl. CPC H10B 12/315; H01L 23/5283; H10B 12/0335; H10B 12/482

(57) ABSTRACT

A semiconductor memory device includes a substrate including cell and peripheral areas, a first interlayer insulating film on the substrate, a first capping film on the first interlayer insulating film, a cell gate structure in the cell area, a first bit-line structure on the cell area, a peripheral gate structure on the peripheral area, and a peripheral contact plug disposed at the peripheral area and extending through the first capping film and the first interlayer insulating film. The first capping film includes a first portion overlapping an upper surface of the peripheral gate structure and a second portion adjacent to a sidewall of the peripheral contact plug. An upper surface of the first portion is lower than an upper surface of the second portion. A width of the first plug portion is equal to a width of the second plug portion.

### CROSS-REFERENCE TO RELATED APPLICATION

This application claims priority from Korean Patent Application No. 10-2023-0066859 filed on May 24, 2023 in the Korean Intellectual Property Office, and all the benefits accruing therefrom under 35 U.S.C. 119, the contents of which in its entirety are herein incorporated by reference.

### BACKGROUND

### Field

The present disclosure relates to a semiconductor memory device and a method of manufacturing the same.

### Description of Related Art

As a semiconductor device becomes highly integrated, individual circuit patterns are becoming more miniaturized to implement a larger number of semiconductor devices in the same area. As an integration level of the semiconductor device increases, a design rule of each of components of the semiconductor device decreases.

For example, a critical dimension of each of circuit patterns constituting a semiconductor device may reduce and an arrangement density of the circuit patterns may increase. Accordingly, the complexity of the process may increase due to an increased number of photolithography and etching processes in forming circuit patterns, and defects may occur when forming the circuit patterns.

### SUMMARY

A technical purpose to be achieved by the present disclosure is to provide a semiconductor memory device having improved reliability and performance.

Another technical purpose to be achieved by the present disclosure is to provide a method for manufacturing a semiconductor memory device having improved reliability and performance.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims and combinations thereof.

According to an aspect of the present disclosure, a semiconductor memory device includes a substrate including a cell area and a peripheral area adjacent to the cell area, a first interlayer insulating film disposed on the substrate, a first capping film disposed on the first interlayer insulating film, a cell gate structure buried in the cell area of the substrate, a first bit-line structure disposed on the cell area of the substrate, a peripheral gate structure disposed on the peripheral area of the substrate, and a peripheral contact plug disposed at the peripheral area and extending through the first capping film and the first interlayer insulating film. The first capping film includes a first portion overlapping an upper surface of the peripheral gate structure and a second portion adjacent to a sidewall of the peripheral contact plug. An upper surface of the first portion is lower than an upper surface of the second portion. The peripheral contact plug includes a first plug portion contacting the first interlayer insulating film, and a second plug portion contacting the first capping film. A width of the first plug portion is equal to a width of the second plug portion.

According to an aspect of the present disclosure, a semiconductor memory device includes a substrate including a cell area and a peripheral area adjacent to the cell area, a first interlayer insulating film disposed on the substrate, a first capping film disposed on the first interlayer insulating film, a cell gate structure buried in the cell area of the substrate, a bit-line structure disposed on the cell area of the substrate, a peripheral gate structure disposed on the peripheral area of the substrate, and a peripheral contact plug disposed at the peripheral area and extending through the first capping film and the first interlayer insulating film into the substrate. A lower end of the peripheral contact plug is buried in the substrate. A height of an upper surface of the first capping film pattern at a first position closest to a center of an upper surface of the peripheral gate structure is smaller than a height of the upper surface of the first capping film pattern at a second position closest to an upper end of the peripheral contact plug.

According to an aspect of the present disclosure, a method of manufacturing a semiconductor memory device includes providing a substrate including a cell area and a peripheral area adjacent to the cell area, forming a cell gate structure buried in the cell area of the substrate, forming a bit-line structure disposed on the cell area of the substrate, forming a pair of peripheral gate structures disposed on the peripheral area of the substrate, forming a first interlayer insulating film in a space between the pair of peripheral gate structures, forming a first capping film on the first interlayer insulating film, the first capping film covering the bit-line structure and the pair of peripheral gate structures, sequentially forming a first sacrificial film, a second capping film and a photoresist film on the first capping film, patterning the photoresist film to form a photoresist pattern with a first opening exposing the second capping film, etching a portion of the second capping film using the photoresist pattern to form a second capping film pattern, etching a portion of the first sacrificial film using the photoresist pattern to form a first sacrificial film pattern, forming a second sacrificial film on the first capping film, the second sacrificial film surrounding the second capping film pattern and the first sacrificial film pattern, removing the first sacrificial film pattern to form a second opening exposing an upper surface of the first capping film, forming a third opening in the first interlayer insulating film between the pair of peripheral gate structures using the second opening, an inner sidewall of the third opening being vertically aligned with an inner sidewall of the second opening, and a bottom surface of the third opening being lower than an upper surface of the substrate, and forming a peripheral contact plug in the second and third openings that are connected with each other.

Other details of the present disclosure are included in the detailed descriptions and drawings.

### BRIEF DESCRIPTION OF DRAWINGS

The above and other aspects and features of the present disclosure will become more apparent by describing in detail illustrative embodiments thereof with reference to the attached drawings, in which:

FIG. 1 is a layout of a semiconductor memory device according to some embodiments;

FIG. 2 is a cross-sectional view as taken along line A-A in FIG. 1;

FIG. 3 is a cross-sectional view as taken along line B-B in FIG. 1;

FIG. 4 is a cross-sectional view as taken along line C-C in FIG. 1;

FIG. 5 is a cross-sectional view as taken along line D-D of FIG. 1;

FIG. 6 is an enlarged view of a R portion of FIG. 5;

FIG. 7 to FIG. 9 are enlarged views of the R portion of FIG. 5 according to some embodiments.

FIG. 10 to FIG. 31 are diagrams of intermediate structures corresponding to intermediate steps for illustrating a method for manufacturing a semiconductor memory device in accordance with some embodiments.

### DETAILED DESCRIPTIONS

For simplicity and clarity of illustration, elements in the drawings are not necessarily drawn to scale. The same reference numbers in different drawings represent the same or similar elements, and as such perform similar functionality. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure. Examples of various embodiments are illustrated and described further below. It will be understood that the description herein is not intended to limit the claims to the specific embodiments described. On the contrary, it is intended to cover alternatives, modifications, and equivalents as may be included in the spirit and scope of the present disclosure as defined by the appended claims.

A shape, a size, a ratio, an angle, a number, etc. disclosed in the drawings for illustrating embodiments of the present disclosure are illustrative, and the present disclosure is not limited thereto. The same reference numerals refer to the same elements herein. Further, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The terminology used herein is for the purpose of describing particular embodiments only and is not intended to limit the present disclosure. As used herein, the singular forms “a” and “an” are intended to include the plural forms as well, unless the context clearly indicates otherwise. It will be further understood that the terms “comprise”, “comprising”, “include”, and “including” when used in this specification, specify the presence of the stated features, integers, operations, elements, and/or components, but do not preclude the presence or addition of one or more other features, integers, operations, elements, components, and/or portions thereof. As used herein, the term “and/or” includes any and all combinations of one or more of the associated listed items. Expression such as “at least one of” when preceding a list of elements may modify an entirety of list of elements and may not modify the individual elements of the list. When referring to “C to D”, this means C inclusive to D inclusive unless otherwise specified.

It will be understood that, although the terms “first”, “second”, “third”, and so on may be used herein to illustrate various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In addition, it will also be understood that when a first element or layer is referred to as being present “on” or “beneath” a second element or layer, the first element may be disposed directly on or beneath the second element or may be disposed indirectly on or beneath the second element with a third element or layer being disposed between the first and second elements or layers. It will be understood that when an element or layer is referred to as being “connected to”, or “coupled to” another element or layer, it may be directly on, connected to, or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present.

Further, as used herein, when a layer, film, region, plate, or the like may be disposed “on” or “on a top” of another layer, film, region, plate, or the like, the former may directly contact the latter or still another layer, film, region, plate, or the like may be disposed between the former and the latter. As used herein, when a layer, film, region, plate, or the like is directly disposed “on” or “on a top” of another layer, film, region, plate, or the like, the former directly contacts the latter and still another layer, film, region, plate, or the like is not disposed between the former and the latter. Further, as used herein, when a layer, film, region, plate, or the like may be disposed “below” or “under” another layer, film, region, plate, or the like, the former may directly contact the latter or still another layer, film, region, plate, or the like may be disposed between the former and the latter. As used herein, when a layer, film, region, plate, or the like is directly disposed “below” or “under” another layer, film, region, plate, or the like, the former directly contacts the latter and still another layer, film, region, plate, or the like is not disposed between the former and the latter.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In one example, when a certain embodiment may be implemented differently, a function or operation specified in a specific block may occur in a sequence different from that specified in a flowchart. For example, two consecutive blocks may be actually executed at the same time. Depending on a related function or operation, the blocks may be executed in a reverse sequence.

In descriptions of temporal relationships, for example, temporal precedent relationships between two events such as “after”, “subsequent to”, “before”, etc., another event may occur therebetween unless “directly after”, “directly subsequent” or “directly before” is not indicated. The features of the various embodiments of the present disclosure may be partially or entirely combined with each other, and may be technically associated with each other or operate with each other. The embodiments may be implemented independently of each other and may be implemented together in an association relationship. Spatially relative terms, such as “beneath,” “below,” “lower,” “under,” “above,” “upper,” and the like, may be used herein for ease of illustration to illustrate one element or feature's relationship to another element or feature as illustrated in the figures. It will be understood that the spatially relative terms are intended to encompass different orientations of the device in use or in operation, in addition to the orientation depicted in the figures. For example, when the device in the drawings may be turned over, elements described as “below” or “beneath” or “under” other elements or features would then be oriented “above” the other elements or features. Thus, the example terms “below” and “under” may encompass both an orientation of above and below. The device may be otherwise oriented, for example, rotated 90 degrees or at other orientations, and the spatially relative descriptors used herein should be interpreted accordingly.

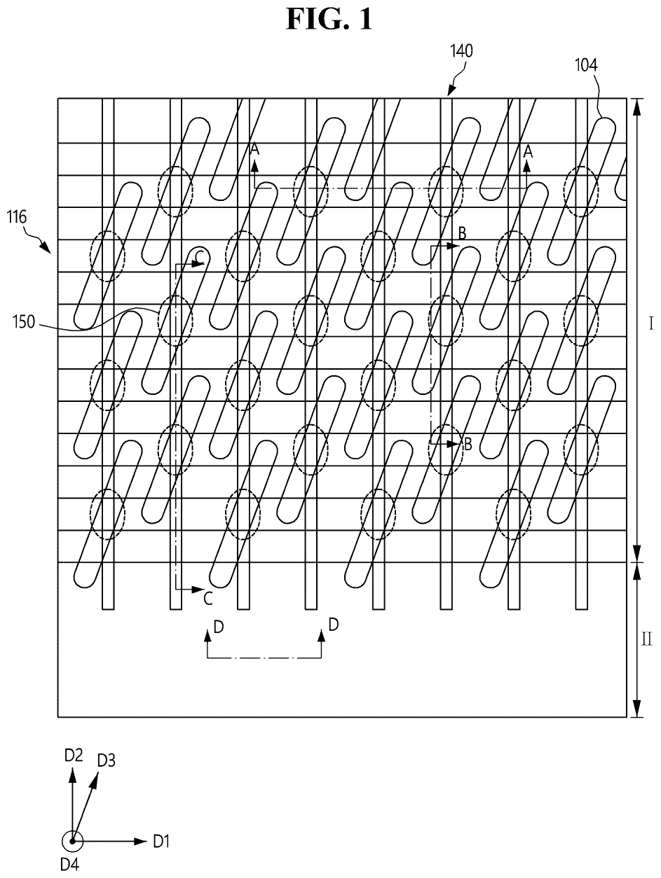

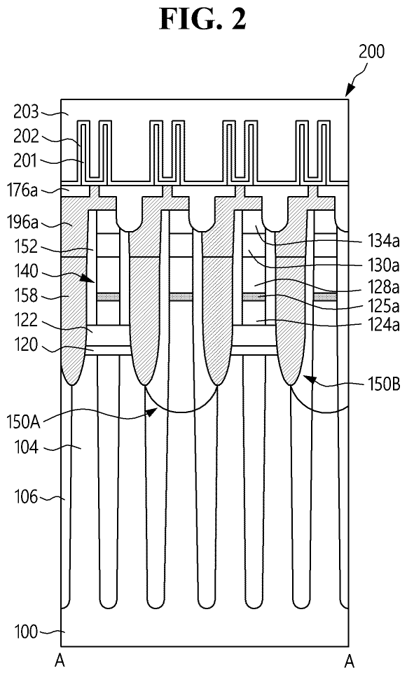

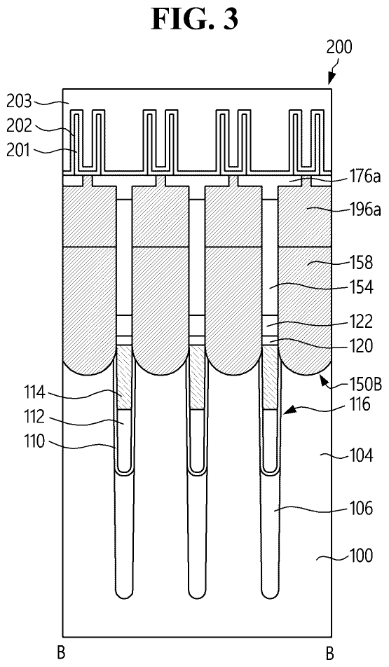

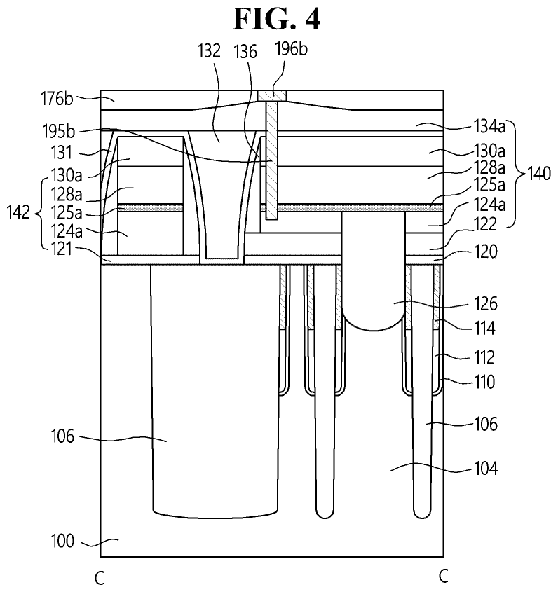

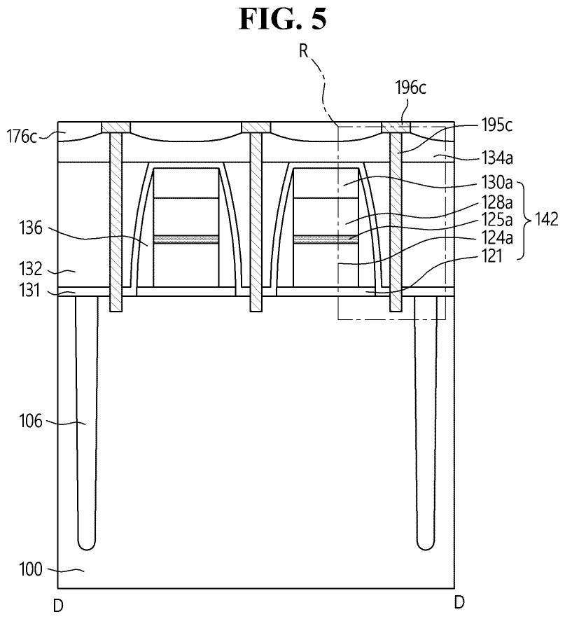

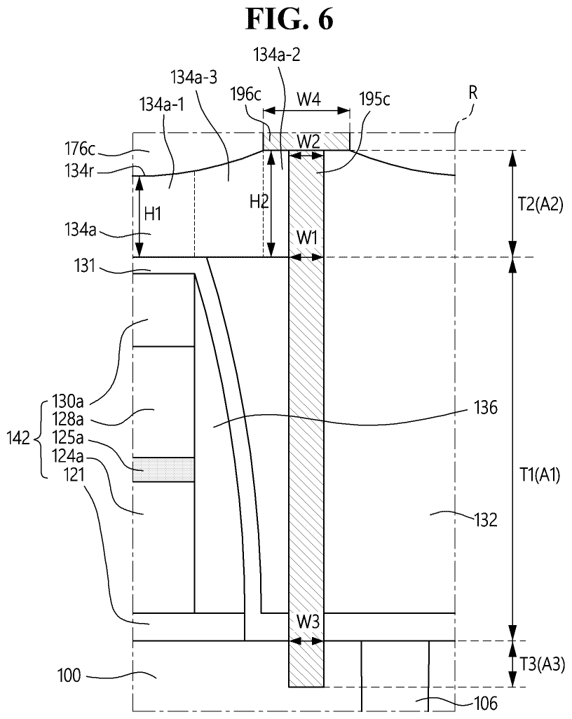

FIG. 1 is a layout of a semiconductor memory device according to some embodiments. FIG. 2 is a cross-sectional view as taken along line A-A in FIG. 1. FIG. 3 is a cross-sectional view as taken along line B-B in FIG. 1. FIG. 4 is a cross-sectional view as taken along line C-C in FIG. 1. FIG. 5 is a cross-sectional view as taken along line D-D of FIG. 1. FIG. 6 is an enlarged view of a R portion of FIG. 5.

In the drawing of the semiconductor memory device according to some embodiments, a DRAM (dynamic random access memory) is illustrated by way of an example. However, the present disclosure is not limited thereto.

The semiconductor memory device according to some embodiments may include a substrate 100, an interlayer insulating film 132, a first gate structure 116, a bit-line structure 140, a second gate structure 142, and a peripheral contact plug 195. In some embodiments, the first gate structure 116 may be referred to as a cell gate structure, and the second gate structure 142 may be referred to as a peripheral gate structure. In some embodiments, the first gate structure 116 may be formed as a buried gate structure.

Referring to FIG. 1 to FIG. 5, the semiconductor memory device may include a substrate 100 including a cell area I and a peripheral area II disposed around the cell area I. The first gate structure 116 may be buried in the cell area I of the substrate 100. The bit-line structure 140, a spacer structure 152, an insulating pattern 154, a lower contact plug 158, an upper contact plug 196a, and a capacitor structure 200 may be formed on the cell area I of the substrate 100. At the peripheral area II of the substrate 100, the second gate structure 142, the interlayer insulating film 132, a bit-line contact plug 195b (i.e., a first peripheral contact plug), a peripheral contact plug 195c (i.e., a second peripheral contact plug), and connection wirings 196b and 196c may be formed. In some embodiments, the upper contact plug 196a may serve as a landing pad which facilitates connection between the lower contact plug 158 and the capacitor structure 200.

The substrate 100 may include or may be formed of silicon, germanium, silicon-germanium, or a group III-V compound such as GaP, GaAs, and GaSb. According to some embodiments, the substrate 100 may be embodied as a silicon-on-insulator (SOI) substrate or a germanium-on-insulator (GOI) substrate.

An element isolation trench may be defined in the substrate 100, and an element isolation pattern 106 may be formed in the element isolation trench. A portion of the substrate 100 between element isolation trenches may act as an active pattern 104. The element isolation pattern 106 may include or may be formed of, for example, silicon oxide or silicon nitride.

A first direction D1 may refer to a direction in which the first gate structure 116 extends, and a second direction D2 may refer to a direction in which the bit-line structure 140 extends. For example, the active pattern 104 may extend in a third direction D3. The third direction D3 may extend between the first and second directions D1 and D2. The first to third directions D1 to D3 may be on the same plane parallel to an upper surface of the substrate 100. As the active pattern 104 extends along the third direction DR3, an angle defined between the first gate structure 116 and the active pattern 104 may be smaller than 90 degrees. A fourth direction D4 may be orthogonal to the first direction D1, the second direction D2, and the third direction D3. The fourth direction D4 may refer to a thickness direction of the substrate 100, and may be a direction perpendicular to the upper surface of the substrate 100.

The first gate structure 116 may be disposed in the cell area I of the substrate 100. The first gate structure 116 may extend through an upper portion of each of the active pattern 104 and the element isolation pattern 106 and extend in the first direction D1. For example, the first gate structure 116 may be buried in the cell area I of the substrate 100. The first gate structure 116 may be provided in a plurality of first gate structures 116 spaced apart from each other in the second direction D2. The first gate structure 116 may include a first gate insulating film 110, a gate electrode 112, and a capping mask pattern 114.

The first gate insulating film 110 may be formed on a surface of the active pattern 104. The gate electrode 112 may extend in the first direction D1 while being disposed on the first gate insulating film 110 and the element isolation pattern 106. The capping mask pattern 114 may cover an upper surface of the gate electrode 112.

The first gate insulating film 110 may include or may be formed of, for example, an oxide such as silicon oxide. The gate electrode 112 may include or may be formed of, for example, a metal such as tungsten (W), titanium (Ti), and tantalum (Ta), or a metal nitride such as tungsten nitride, titanium nitride, and tantalum nitride. The capping mask pattern 114 may include or may be formed of, for example, a nitride such as silicon nitride.

A first insulating film 120 and a second insulating film 122 may be sequentially stacked on the active pattern 104, the element isolation pattern 106, and the capping mask pattern 114 and may be disposed on the cell area I. A second gate insulating film 121 may be formed on the active pattern 104 and on the peripheral area II.

The bit-line structure 140 on the cell area I may include a first conductive pattern 124a, a barrier pattern 125a, a second conductive pattern 128a, a first capping film pattern 130a, and a second capping film pattern 134a sequentially stacked. In some embodiments, the bit-line structure 140 may extend in the second direction D2 while being disposed on the active pattern 104 and the second insulating film 122.

A portion of the first conductive pattern 124a included in the bit-line structure 140 may be formed in a first opening 150A formed on an upper surface of the active pattern 104, and an upper surface of each of the element isolation pattern 106 and the capping mask pattern 114 adjacent thereto. Accordingly, a portion of the first conductive pattern 124a may contact the upper surface of the active pattern 104 exposed through the first opening 150A. The term “contact,” as used herein, refers to a direct connection (i.e., physical touching) unless the context indicates otherwise.

Each of the first and second conductive patterns 124a and 128a may include or may be formed of at least one of, for example, a semiconductor material doped with impurities, a conductive silicide compound, a conductive metal nitride metal, and a metal alloy. For example, the first conductive pattern 124a may include or may be formed of a doped semiconductor material, and the second conductive pattern 128a may include or may be formed of at least one of a metal and a metal alloy. However, the present disclosure is not limited thereto.

The barrier pattern 125a may include or may be formed of, for example, at least one of a conductive silicide compound and a conductive metal nitride. Each of the first and second capping film patterns 130a and 134a may include or may be formed of, for example, at least one of silicon nitride, silicon oxynitride, silicon carbonitride, and silicon oxycarbonitride.

The second gate structure 142 on the peripheral area II may include the second gate insulating film 121, the first conductive pattern 124a, the barrier pattern 125a, the second conductive pattern 128a, and the first capping film pattern 130a that are sequentially stacked on each other.

Thus, each of the second gate structure 142 on the peripheral area II and the bit-line structure 140 on the cell area I may have a structure in which the first conductive pattern 124a, the barrier pattern 125a, the second conductive pattern 128a, and the first capping film pattern 130a are stacked on each other.

A spacer 136 (i.e., a gate spacer) may be disposed on a sidewall of the second gate structure 142. The bit-line structure 140 may extend from the cell area I to a portion of the peripheral area II. The spacer 136 may be disposed at an end portion, in the second direction D2, of the bit-line structure 140 that is disposed on the peripheral area II.

An insulating liner 131 may cover the first capping film pattern 130a while being disposed on the cell area I, and may extend to the peripheral area II. For example, the insulating liner 131 may cover upper surfaces of the substrate 100 and the element isolation pattern 106. The second capping film pattern 134a may cover the insulating liner 131 while being disposed on the cell area I. In some embodiments, the insulating liner 131 and the second capping film pattern 134 may be formed both on the cell area I and the peripheral area II.

The interlayer insulating film 132 may be disposed on the substrate 100 and between the second gate structures 142. The second capping film pattern 134a may be disposed on the second gate structure 142 and the interlayer insulating film 132 on the peripheral area II.

A spacer structure 152 (i.e., a bit-line spacer) may be formed on each of opposite sidewalls of the bit-line structure 140. For example, a pair of bit-line spacers that are spaced apart from each other in the first direction D1 may be formed on opposite sidewalls of the bit-line structure 140 that extends in the second direction D2. Accordingly, the spacer structure 153 may extend in the second direction D2. In some embodiments, the spacer structure 152 may include a plurality of spacers stacked on each of both opposite sidewalls of the bit-line structure 140. In some embodiments, the spacer structure 152 may include an air spacer or an air gap embodied as an empty space. The phrase “air gap” or “air spacer” will be understood to include gaps (e.g., pockets) of air or gases other than air, such as other atmospheric gases or chamber gases that may be present during manufacturing. In some embodiments, an upper surface of the spacer structure 152 may be coplanar with an upper surface of the bit-line structure 140 (see FIG. 2).

The insulating pattern 154 may be formed on the second insulating film 122. The insulating pattern 154 may be positioned on the first gate structure 116 and between the bit-line structures 140. In some embodiments, the insulating pattern 154 may be disposed on an upper surface of the first gate structure 116 and in a space between two adjacent stacked structures of the lower and upper contact plugs 158 and 196a (see FIG. 3).

In some embodiments, an upper surface of the insulating pattern 154 may be coplanar with an upper surface of the bit-line structure 140. The insulating pattern 154 may include or may be formed of, for example, at least one of silicon oxide, silicon nitride, silicon oxynitride, and a combination thereof.

A second opening 150B exposing the active pattern 104 may be formed between the bit-line structures 140 and between the insulating patterns 154. The lower contact plug 158 and the upper contact plug 196a may be formed in the second opening 150B.

The lower contact plug 158 may fill a lower portion of the second opening 150B. The lower contact plug 158 may include or may be formed of, for example, a doped semiconductor material such as doped silicon and doped germanium, or a metal such as titanium, tantalum, tungsten, copper, and aluminum.

In some embodiments, an upper surface of the lower contact plug 158 may be positioned at a higher level than that of an upper surface of the first conductive pattern 124a included in the bit-line structure 140 and at a lower level than that of an upper surface of the first capping film pattern 130a (see FIG. 2). The upper surface of the lower contact plug 158 may be coplanar with an upper surface of the second conductive pattern 128a. However, a position of the upper surface of the lower contact plug 158 may not be limited thereto. In some embodiments, the upper surface of the lower contact plug 158 may be adjacent to a sidewall of the second conductive pattern 128a (i.e., may be lower than the upper surface of the second conductive pattern 128a).

The upper contact plug 196a may contact the upper surface of the lower contact plug 158. The upper contact plug 196a may include or may be formed of, for example, a doped semiconductor material such as doped silicon and doped germanium, or a metal such as titanium, tantalum, tungsten, copper, and aluminum.

First to third isolation insulating films 176a, 176b, and 176c may be disposed on the upper contact plug 196a and the bit-line structure 140 that are disposed on the cell area I and on the second capping film pattern 134a on the peripheral area II.

The first isolation insulating film 176a may define an area of the upper contact plug 196a constituting each of a plurality of isolated areas. The first isolation insulating film 176a may cover an upper surface of the upper contact plug 196a. The present disclosure is not limited thereto. In some embodiments, the first isolation insulating film 176a may not cover the upper surface of the upper contact plug 196a.

The second isolation insulating film 176b may insulate a plurality of first connection wirings 196b from each other. The second isolation insulating film 176b may not cover an upper surface of the first connection wiring 196b. In some embodiments, an upper surface of the second isolation insulating film 176 may be coplanar with the upper surface of the first connection wiring 196b. The third isolation insulating film 176c may insulate a plurality of second connection wirings 196c from each other. The third isolation insulating film 176c may not cover an upper surface of the second connection wiring 196c. In some embodiments, an upper surface of the third isolation insulating film 176c may be coplanar with the upper surface of the second connection wiring 196c.

The peripheral contact plugs 195b and 195c may extend through the second capping film pattern 134a and the interlayer insulating film 132 while being disposed at the peripheral area II.

The first peripheral contact plug 195b may be located at an end portion, in the second direction D2, of the bit-line structure 140 extending to the peripheral area II. The end potion of the bit-line structure 140 may be disposed on the peripheral area II. The first peripheral contact plug 195b may extend through an upper portion of the bit-line structure 140 so as to contact the first and second conductive patterns 124a and 128a of the bit-line structure 140. The second peripheral contact plug 195c may be disposed in the peripheral area II and may be disposed on each of both opposite sides of the second gate structure 142, and may extend through the second capping film pattern 134a and the interlayer insulating film 132 to contact the substrate 100. In some embodiments, a lower end of the second peripheral contact plug 195c may be buried in the peripheral area II.

The first connection wiring 196b may be connected to the first peripheral contact plug 195b while being disposed in the second isolation insulating film 176b. The first connection wiring 196b may extend along and contact a top of the first peripheral contact plug 195b. The second connection wiring 196c may be connected to the second peripheral contact plug 195c while being disposed in the third isolation insulating film 176c. The second connection wiring 196c may extend along and contact a top of the second peripheral contact plug 195c.

Although not specifically shown, each of the peripheral contact plugs 195b and 195c, the first connection wiring 196b, and the second connection wiring 196c may include a barrier pattern and a metal pattern.

The upper contact plug 196a, the first peripheral contact plug 195b, the first connection wiring 196b, the second peripheral contact plug 195c, and the second connection wiring 196c may include or may be formed of the same conductive material. For example, the barrier patterns of the upper contact plug 196a, the first peripheral contact plug 195b, the first connection wiring 196b, the second peripheral contact plug 195c, and the second connection wiring 196c may include or may be formed of the same material. The metal patterns of the upper contact plug 196a, the first peripheral contact plug 195b, the first connection wiring 196b, the second peripheral contact plug 195c, and the second connection wiring 196c may include or may be formed of the same material.

The capacitor structure 200 may be disposed on the upper contact plug 196a and may store therein charges and act as a component of a semiconductor memory device. The upper contact plug 196a may constitute a landing pad electrically connected to the capacitor structure 200. The lower contact plug 158 may constitute a buried contact between the bit-line structures 140.

The capacitor structure 200 may be connected to a portion of an upper surface of the upper contact plug 196a not covered with the first isolation insulating film 176a. As a result, the capacitor structure 200 may be electrically connected to a source/drain area connected to the lower contact plug 158, and may store therein charges and act as data storage of the semiconductor memory device.

The capacitor structure 200 may include a lower electrode 201, a capacitance dielectric film 202, and an upper electrode 203 and may store therein charges. For example, the capacitor structure 200 may store charges in the capacitance dielectric film 202 due to a difference between a potential of the lower electrode 201 and a potential of the upper electrode 203.

Each of the lower electrode 201 and the upper electrode 203 may include or may be formed of, for example, doped polysilicon, metal, or metal nitride. The capacitance dielectric film 202 may include or may be formed of, for example, silicon oxide or a high-k dielectric material. However, the present disclosure is not limited thereto.

Referring to FIG. 5 and FIG. 6, a recess 134r may be defined on an upper surface of the second capping film pattern 134a and in an area overlapping the peripheral gate structure 142. A height H1 of a portion of the upper surface of the second capping film pattern 134a in a position closest to a center of the peripheral gate structure 142 may be smaller than a height H2 of a portion of the upper surface of the second capping film pattern 134a in a position closest to the second peripheral contact plug 195c. For example, the second capping film pattern 134a on the peripheral area II may have a curved upper surface. The curved upper surface covers both the upper surface of the second gate structure 142 and gradually increases in height from the overlapping section with the upper surface of the second gate structure 142 towards the second connection wiring 196c. In some embodiments, an end of the curved upper surface may contact the second connection wiring 196c. In some embodiments, the heights H1 and H2 may be measured relative to an upper surface of the interlayer insulating film 132, which is coplanar with an uppermost surface of the insulating liner 131. In some embodiments, the second capping film pattern 134a may include a first portion 134a-1 overlapping an upper surface of the peripheral gate structure 142 and a second portion 134a-2 that is adjacent to a sidewall of the peripheral contact plug 195c. An upper surface of the first portion 134a-1 may be lower than an upper surface of the second portion 134a-2. The second capping film pattern 134a may further include a third portion 134a-3 connecting the first portion 134a-1 to the second portion 134a-2. In some embodiments, the first portion 134a-1 of the second capping film pattern 134a may have a flat upper surface and may be disposed under a bottom surface of the second connection wiring 196c. The flat upper surface of the first portion 134-1 may contact the bottom surface of the second connection wiring 196c. The curved upper surface may correspond to upper surfaces of the first and third portions 134a-1 and 143a-3.

The second peripheral contact plug 195c may include a first area A1 (i.e., a first plug portion) contacting the third isolation insulating film 176c, a second area A2 (i.e., a second plug portion) contacting the second capping film pattern 134a, and a third area A3 (i.e., a third plug portion) extending into the substrate 100 and contacting the substrate 100.

Each of sidewalls of the first area A1 to the third area A3 may be perpendicular to the upper surface of the substrate 100. A width of the second peripheral contact plug 195c may be substantially constant along the fourth direction D4. For example, a width W1 of an upper surface of the first area A1, a width W2 of an upper surface of the second area A2, and a width W3 of an upper surface of the third area A3 may be equal to each other. Terms such as “same,” “equal,” “planar,” “constant,” or “coplanar,” as used herein encompass near identicality including variations that may occur, for example, due to manufacturing processes. The term “substantially” may be used herein to emphasize this meaning, unless the context or other statements indicate otherwise.

A sum of a thickness T1 of the first area A1 and a thickness T3 of the third area A3 may be 5 to 7 times of a thickness T2 of the second area A2. However, the present disclosure is not limited thereto.

A width W4 of the second connection wiring 196c may be greater than each of the width W1 of the upper surface of the first area A1, the width W2 of the upper surface of the second area A2, and the width W3 of the upper surface of the third area A3.

Referring to FIG. 4, a recess may be defined on an upper surface of the second capping film pattern 134a and in an area overlapping the peripheral gate structure 142. A height of a portion of the upper surface of the second capping film pattern 134a in an area closest to a center of the peripheral gate structure 142 may be smaller than a height of a portion of the upper surface of the second capping film pattern 134a in an area closest to the first peripheral contact plug 195b. For example, the second capping film pattern 134a on the end portion of the bit-line structure 140 may have a curved upper surface similarly to the second capping film pattern 134 as shown in FIG. 5. The curved upper surface covers both the upper surface of the second gate structure 142 and gradually increases in height from the overlapping section with the upper surface of the second gate structure 142 towards the first connection wiring 196b. In some embodiments, an end of the curved upper surface may contact the first connection wiring 196b.

A sidewall of the first peripheral contact plug 195b may be perpendicular to the upper surface of the substrate 100. A width of the first peripheral contact plug 195b may be substantially constant along the vertical direction D4.

In some embodiments, a profile of the sidewall of each of the peripheral contact plugs 195b and 195c may be perpendicular to the substrate 100. As a result, the distance between the peripheral contact plugs 195b and 195c spaced apart from each other may be increased compared to when sidewalls of the peripheral contact plugs 195b and 195c are slopped or curved, thereby preventing an electrical short between the peripheral contact plugs adjacent to each other and securing a process margin for forming the peripheral contact plugs 195b and 195c with the connection wirings 196b and 196c connected thereto, respectively.

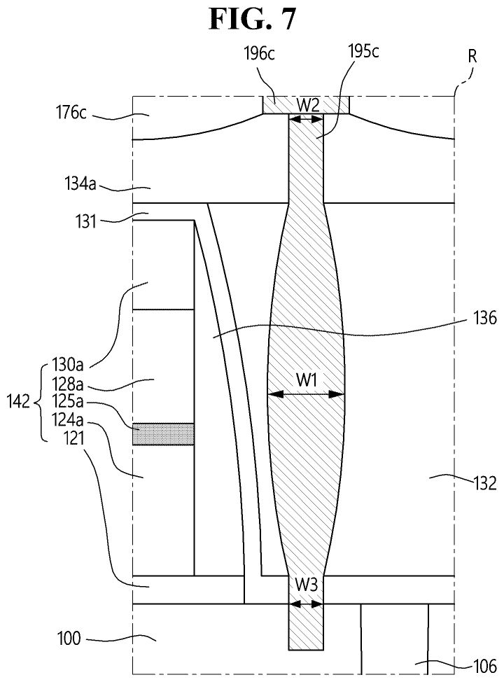

FIG. 7 to FIG. 9 are enlarged views of a R portion of FIG. 5 according to some embodiments. For the convenience of description, differences thereof from the descriptions as set forth above with reference to FIG. 1 to FIG. 6 will be mainly described.

Referring to FIG. 7, the width W1 of a vertical median level of the first area A1 may be greater than each of the width W2 of the second area A2 and the width W3 of the third area A3. The widths W1 to W3 may be measured in a direction parallel to an upper surface of the substrate 100. The width W2 corresponds to a width of an upper end of the second peripheral contact plug 195c, which contacts a bottom surface of the second connection wiring 196c. The width W3 corresponds to a width of the second peripheral contact plug 195c measured at a level of the upper surface of the substrate 100. In this case, a width of the second peripheral contact plug 195c may be minimum in an area adjacent to the second capping film pattern 134a or an area adjacent to the substrate 100.

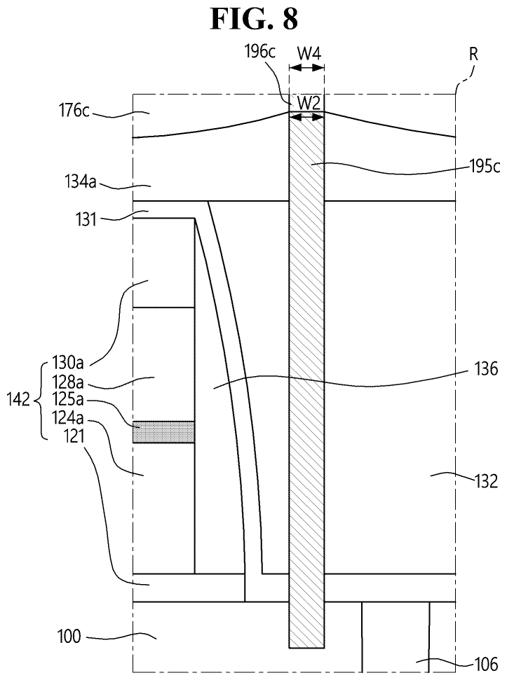

Referring to FIG. 8, the width W4 of the second connection wiring 196c may be substantially the same as each of the width W1 of the first area A1 to the width W3 of the third area A3. The width W4 may be measured in the direction parallel to the upper surface of the substrate 100.

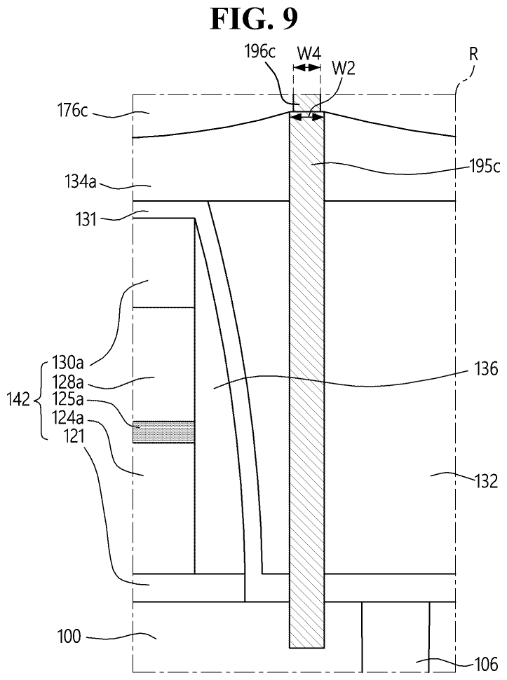

Referring to FIG. 9, the width W4 of the second connection wiring 196c may be smaller than each of the width W1 of the first area A1 to the width W3 of the third area A3.

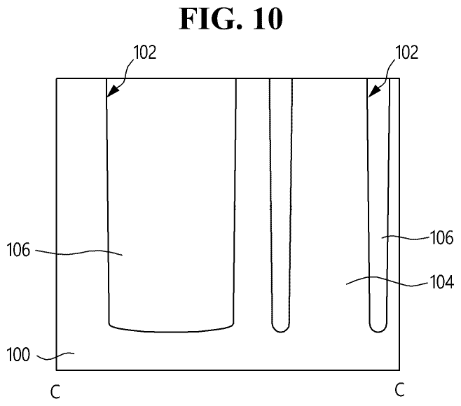

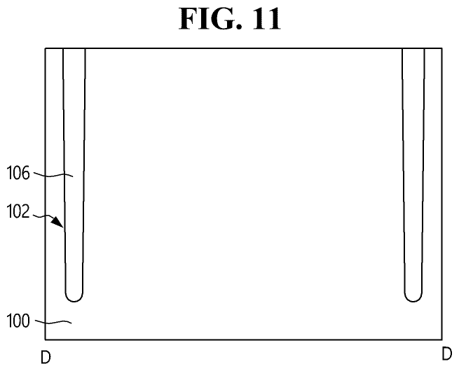

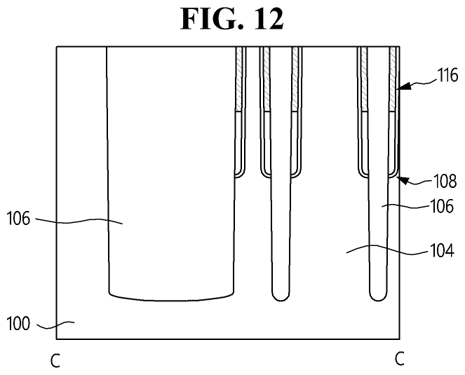

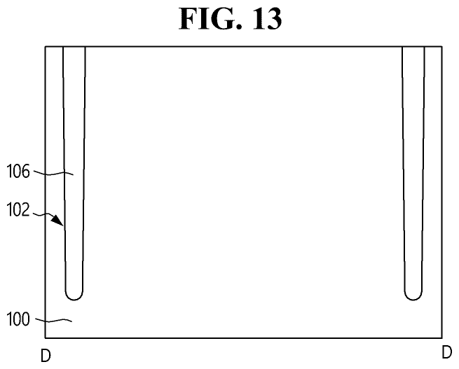

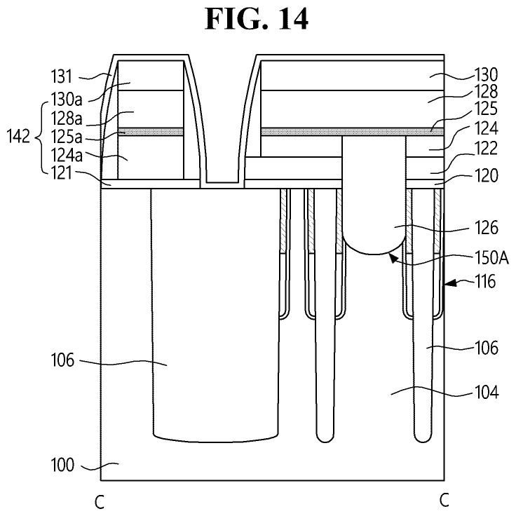

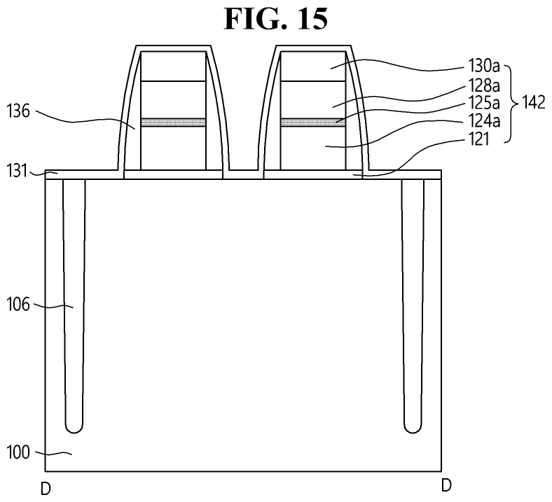

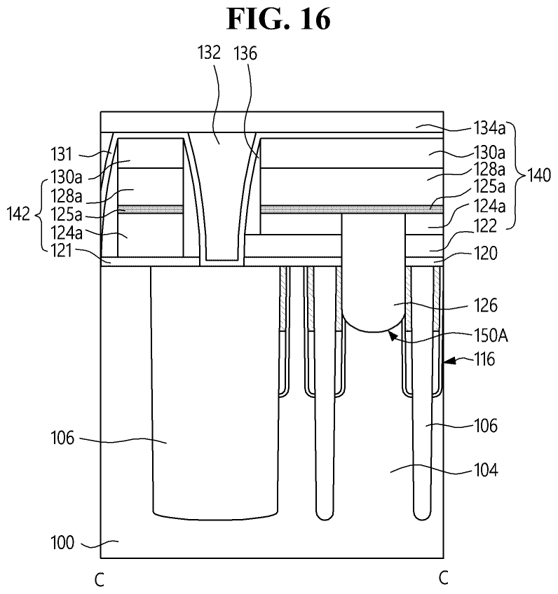

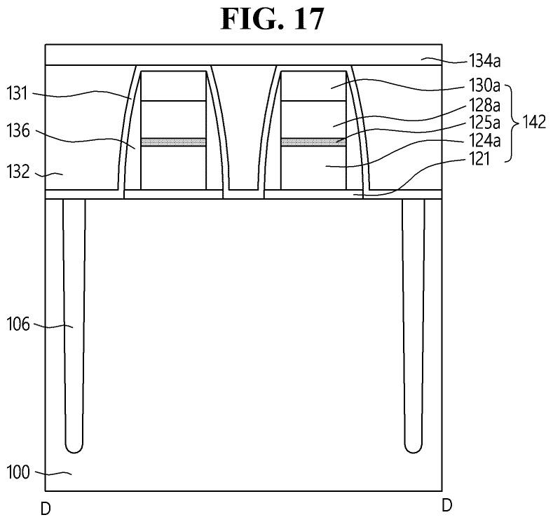

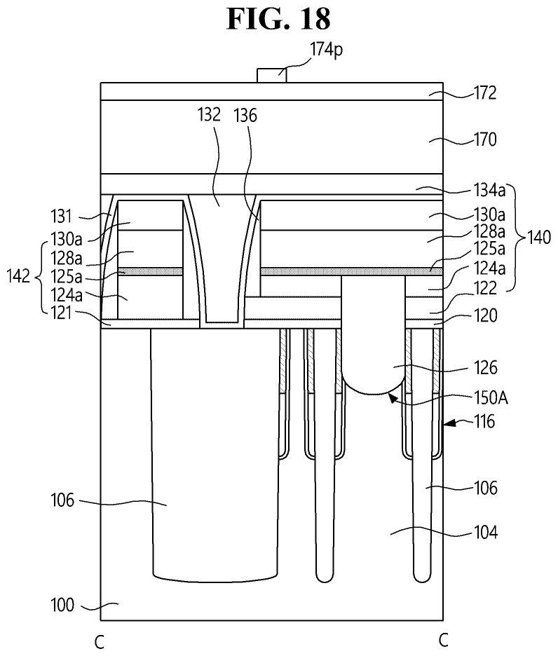

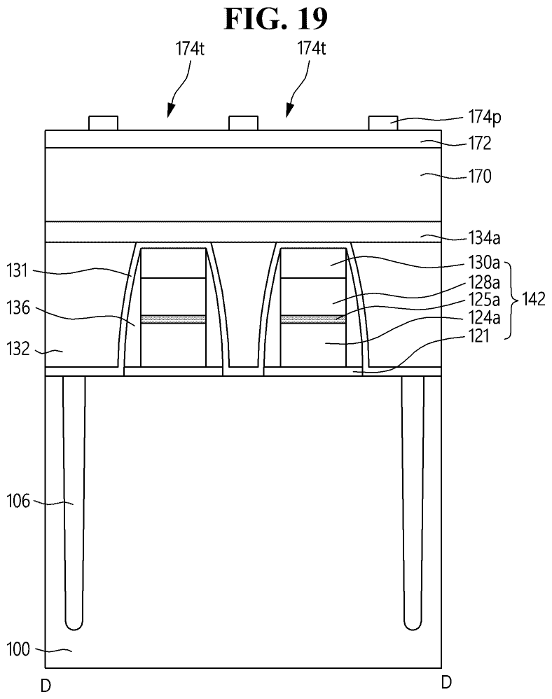

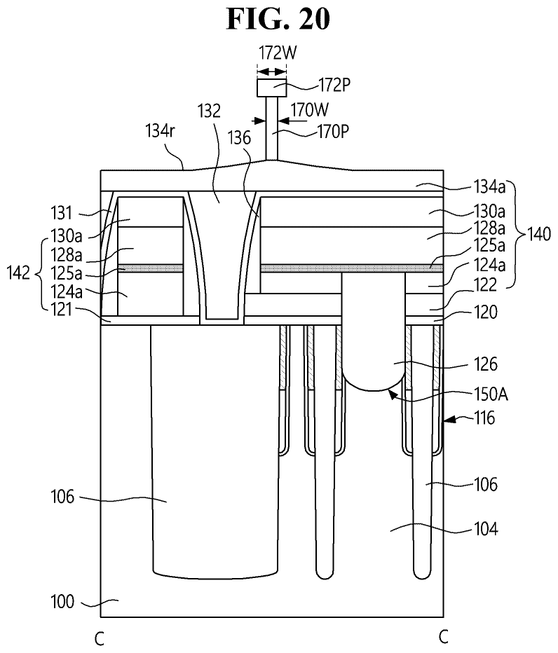

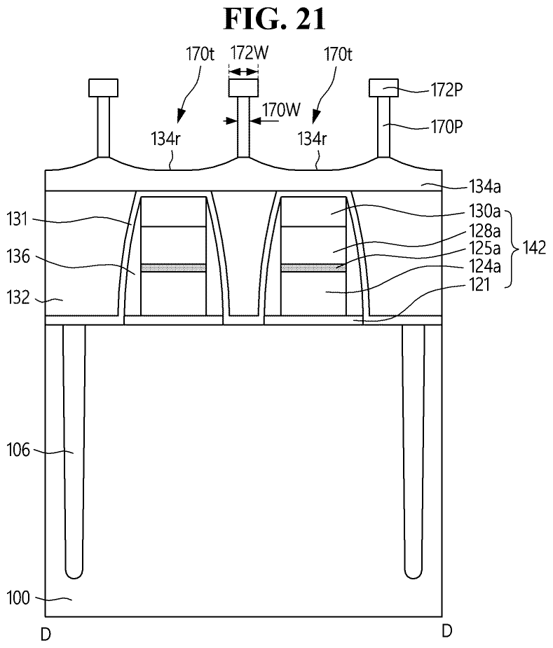

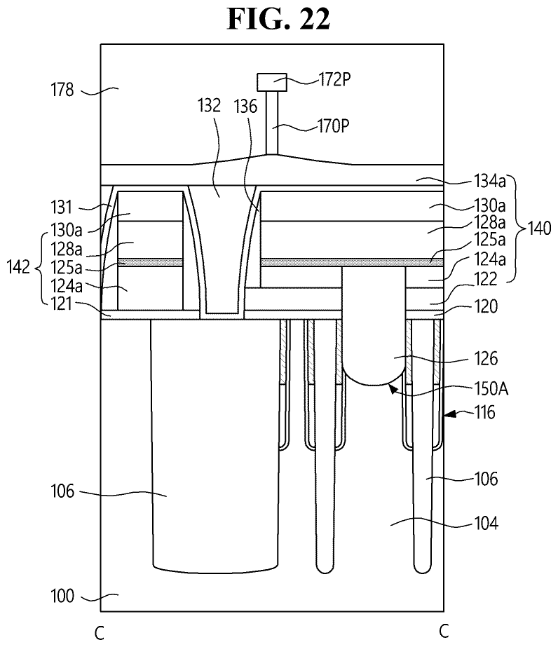

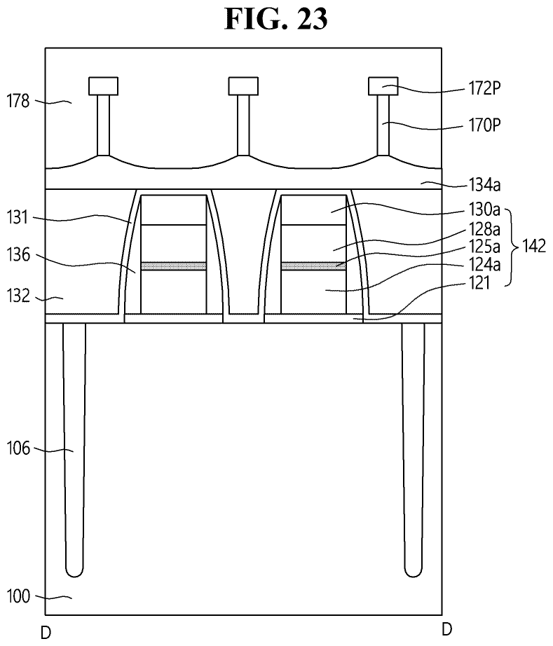

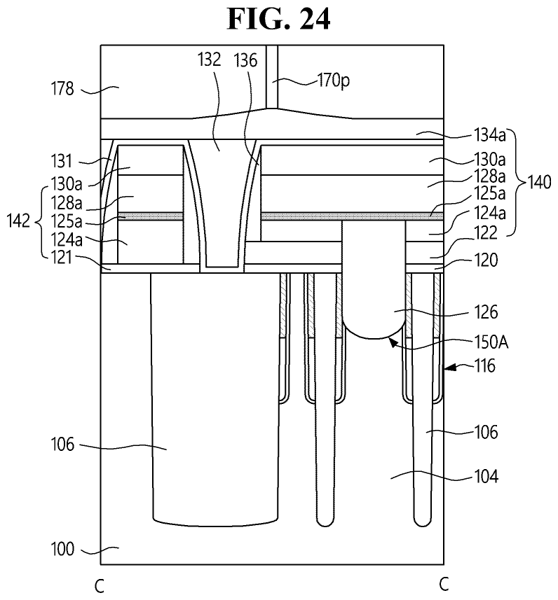

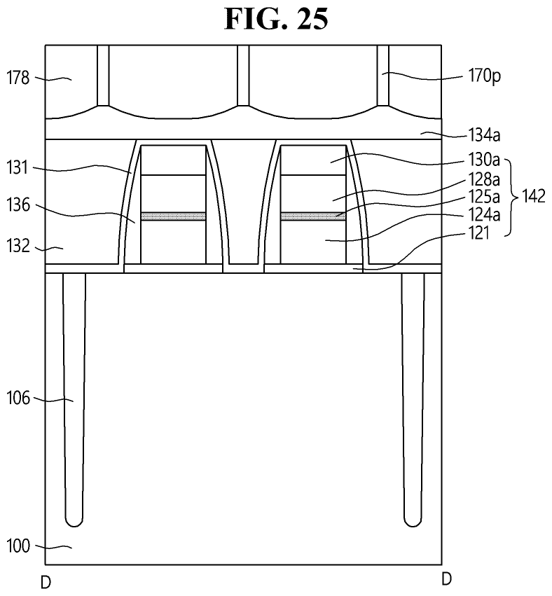

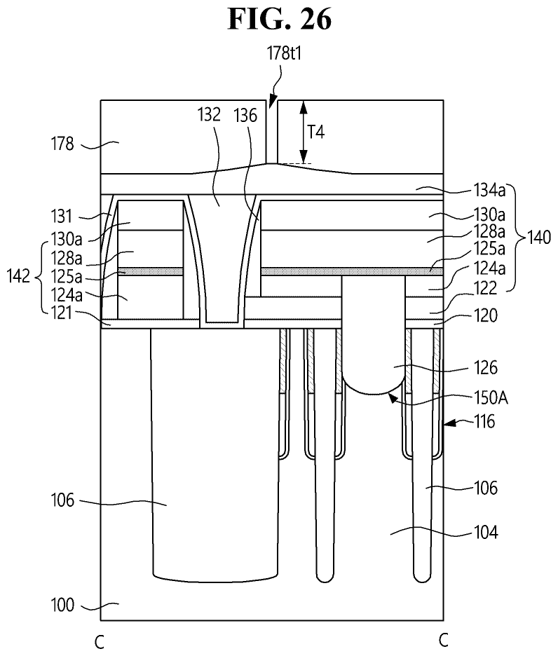

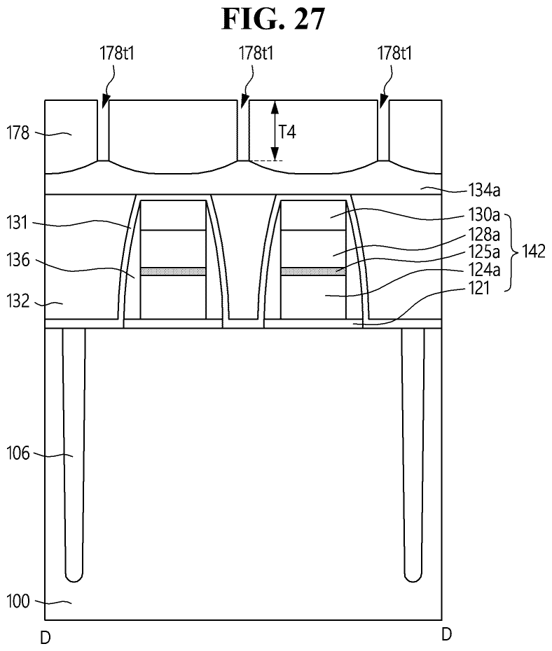

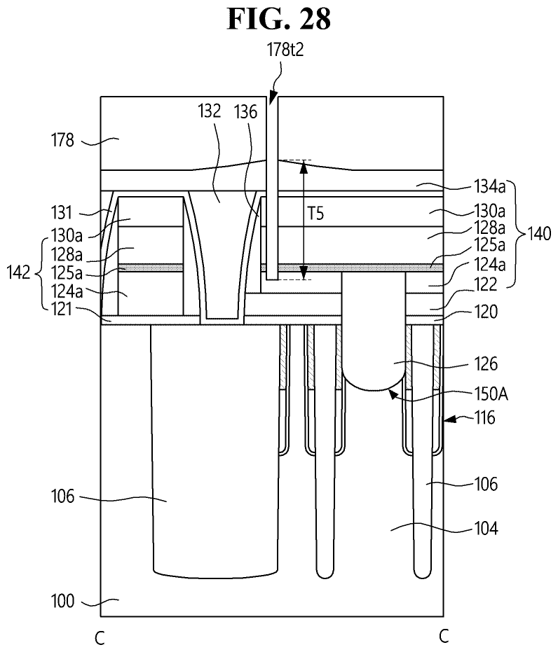

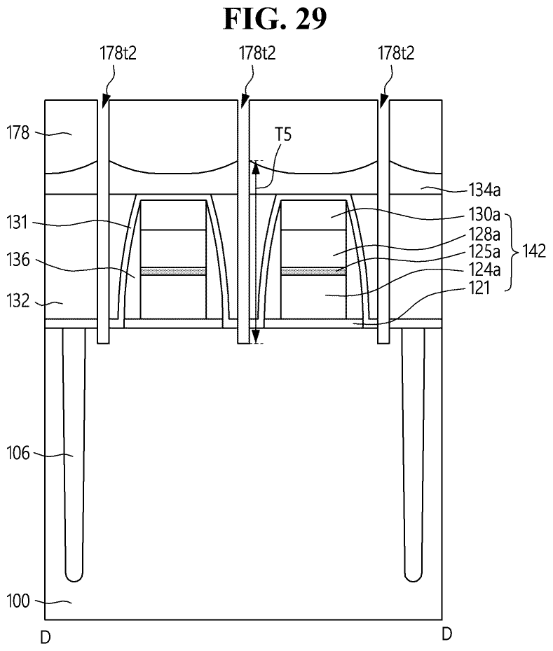

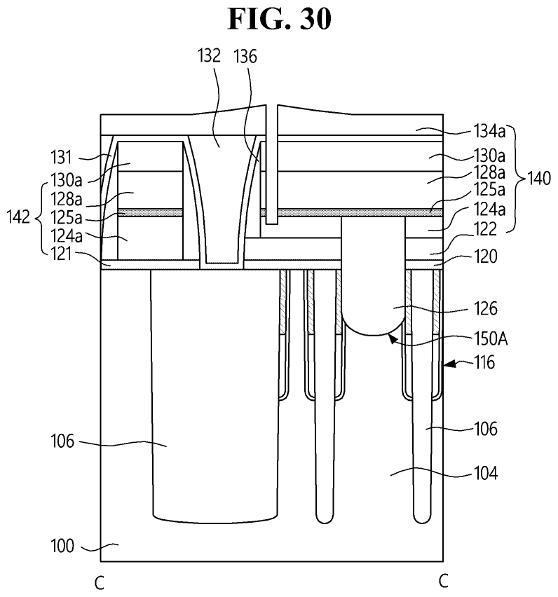

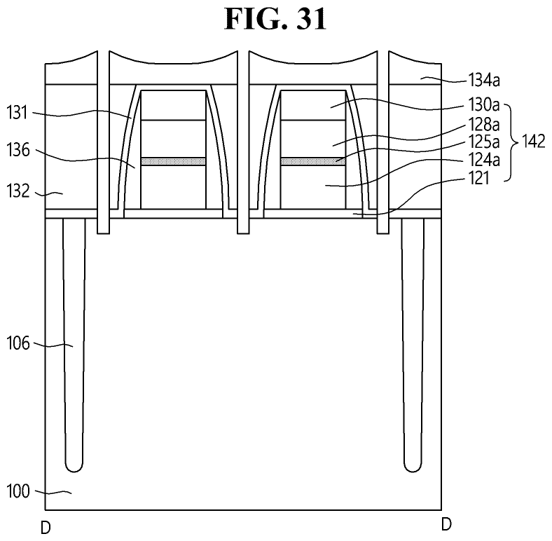

FIG. 10 to FIG. 31 are diagrams of intermediate structures corresponding to intermediate steps for illustrating a method for manufacturing a semiconductor memory device in accordance with some embodiments. For reference, each of FIG. 10, FIG. 12, FIG. 14, FIG. 16, FIG. 18, FIG. 20, FIG. 22, FIG. 24, FIG. 26, FIG. 28, and FIG. 30 is a drawing corresponding to a cross-sectional view taken along line C-C of FIG. 1. Each of FIG. 11, FIG. 13, FIG. 15, FIG. 17, FIG. 19, FIG. 21, FIG. 23, FIG. 25, FIG. 27, FIG. 29, and FIG. 31 is a drawing corresponding to a cross-sectional view taken along line D-D of FIG. 1. For the convenience of description, differences thereof from the descriptions as set forth above with reference to FIG. 1 to FIG. 6 will be mainly described.

Referring to FIG. 10 and FIG. 11, the substrate 100 including the cell area I and the peripheral area II is provided. The cell area I may be an area at which a memory cell is formed, and the peripheral area II may be an area at which a peripheral circuit is formed.

An upper portion of the substrate 100 is etched to form a trench 102, and the element isolation pattern 106 filling an inside of the trench 102 is formed. An area of the substrate 100 between the element isolation patterns 106 may correspond to the active pattern 104. An area where the element isolation pattern 106 is formed may be provided as a field area, and an area where the active pattern 104 is formed may be provided as an active area.

Referring to FIG. 12 and FIG. 13, an impurity area (not shown) may be formed in the cell area I of the substrate 100, for example, by performing an ion implantation process. Then, a gate trench 108 extending in the first direction D1 may be formed by partially etching the active pattern 104 and the element isolation pattern 106 of the cell area I.

The first gate structure 116 may be formed in the gate trench 108. The first gate structure 116 may include the first gate insulating film (110 of FIG. 4), the gate electrode (112 of FIG. 4), and the capping mask pattern (114 of FIG. 4).

Referring to FIG. 14 and FIG. 15, the first insulating film 120 and the second insulating film 122 are sequentially formed on the active pattern 104, element isolation pattern 106, and capping mask pattern 114 of the cell area I. The second gate insulating film 121 is formed on the active pattern 104 of the peripheral area II.

A first conductive film 124 is formed on the second insulating film 122 and the second gate insulating film 121. The first opening 150A exposing the active pattern 104 of the cell area I is formed by partially etching the first conductive film 124, and the second insulating film 122 and the first insulating film 120 disposed under the first conductive film 124 on the cell area I. In some embodiments, the first opening 150A may expose an upper surface of a middle portion of each active pattern 104 of the cell area I.

A second conductive film 126 filling an inside of the first opening 150A is formed. Upper surfaces of the first and second conductive films 124 and 126 may be substantially coplanar with each other. Each of the first and second conductive films 124 and 126 may include or may be formed of polysilicon doped with impurities. Since the first and second conductive films 124 and 126 are made of the same material, the first and second conductive films 124 and 126 may be merged into a single film.

A barrier film 125, a first metal film 128, and a first capping film 130 may be sequentially formed on the upper surface of each of the first and second conductive films 124 and 126.

Although not specifically shown, an etching mask pattern may be formed on the first capping film 130 so as to cover the cell area I and not to cover a portion of the peripheral area II. The first capping film 130, the first metal film 128, the barrier film 125, and the first conductive film 124 formed on the peripheral area II may be sequentially etched using the etching mask pattern. Accordingly, a pre-bit-line structure may be formed on the cell area I.

The second gate structure 142 may be formed on the peripheral area II. The second gate structure 142 has a stack structure in which the second gate insulating film 121, the first conductive pattern 124a, the barrier pattern 125a, the second conductive pattern 128a, and the first capping film pattern 130a may be stacked.

The spacer 136 may be formed on a sidewall of the pre-bit-line structure and the sidewall of the second gate structure 142. In an etching process for forming the spacer 136, a portion of each of the first insulating film 120, the second insulating film 122, and the second gate insulating film 121 disposed between the spacers 136 may be removed. In some embodiments, the insulating liner 131 may be further formed on an upper surface of the pre-bit-line structure, the upper surface of the second gate structure 142, a side surface of the spacer 136, and a portion of the surface of the substrate 100 between the spacers 136. The insulating liner 131 may include or may be formed of silicon nitride. However, the present disclosure is not limited thereto.

Referring to FIGS. 16 and 17, the interlayer insulating film 132 filling a space between the second gate structures 142 may be formed on the peripheral area II of the substrate 100.

A second capping film is formed on the pre-bit-line structure, the second gate structure 142 and the interlayer insulating film 132. The second capping film may include or may be formed of silicon nitride.

The first capping film and the second capping film of the cell area I are patterned. Accordingly, the second capping film pattern 134a and the first capping film pattern 130a may be formed on the cell area I and the peripheral area II. Each of the first and second capping film patterns 130a and 134a on the cell area I may have a line shape extending in the second direction D2. The second capping film pattern 134a may cover an entirety of a top surface of the peripheral area II.

The first metal film 128, the barrier film 125, the second conductive film 126, and the first conductive film 124 of the cell area I may be etched using the first and second capping film patterns 130a and 134a as an etching mask. Accordingly, the second conductive film 126 may be formed in the first opening 150A on the active pattern 104, and then, the barrier pattern 125a, the second conductive pattern 128a, and the first and second capping film patterns 130a and 134a may be sequentially stacked on the second conductive film 126. The first conductive pattern 124a, the barrier pattern 125a, the second conductive pattern 128a, and the first and second capping film patterns 130a and 134a may be sequentially stacked on the second insulating film 122 and in an area out of the first opening 150A.

The first conductive pattern 124a, the barrier pattern 125a, the second conductive pattern 128a, the first capping film pattern 130a, and the second capping film pattern 134a that are sequentially stacked on each other may constitute the bit-line structure 140.

The bit-line structure 140 may extend in the second direction D2. A plurality of bit-line structures 140 may be arranged along the first direction D1. For example, the bit-line structure 140 may extend in the second direction D2 while contacting a portion of the surface of the active pattern 104 exposed through the first openings 150A.

Referring to FIGS. 18 and 19, a first sacrificial film 170, a third capping film 172, and a photoresist layer may be sequentially formed on the bit-line structure 140 and the second capping film pattern 134a.

The first sacrificial film 170 may include or may be formed of silicon oxide. The first sacrificial film 170 may include or may be formed of, for example, TEOS (Tetraethyl orthosilicate). The third capping film 172 may not include oxide. The third capping film 172 may include or may be formed of, for example, silicon nitride.

A photolithography process is performed on the photoresist layer to form a photoresist pattern 174p. The photoresist pattern 174p may serve as an etching mask for forming contact plugs on the cell area I and the peripheral area II.

In the process of patterning the photoresist layer, a first opening 174t having a first sidewall exposing the photoresist pattern 174p and a first bottom surface exposing an upper surface of the third capping film 172 may be formed.

Referring to FIGS. 20 and 21, a portion of the third capping film 172 may be etched to form third capping film patterns 172p spaced apart from each other. A portion of the first sacrificial film 170 may be etched to form first sacrificial film patterns 170p spaced apart from each other. A process of forming the first sacrificial film patterns 170p may be performed using an etching process that selectively removes the oxide.

A width 170W of each of the first sacrificial film patterns 170p may be smaller than a width of 172W of each of the third capping film patterns 172p. The widths 170W and 172W may be measured in a direction parallel to an upper surface of the substrate 100.

When forming the first sacrificial film patterns 170p, a recess 134r may be formed on an upper surface of the second capping film pattern 134a. The recess 134r may be defined on the upper surface of the second capping film pattern 134a and in an area overlapping the peripheral gate structures 142.

For example, when hydrofluoric acid (HF) is used in the process of forming the first sacrificial film patterns 170p, at least a portion of the second capping film pattern 134a may be etched to form the recess 134r. Accordingly, a height of a portion of an upper surface of the second capping film pattern 134a in the area closest to the center of the peripheral gate structures 142 may be smaller than a height of a portion of the upper surface of the second capping film pattern 134a in the area closest to each of the peripheral contact plugs (195b and 195c in FIG. 4 and FIG. 5). In some embodiments, a directional dry etching process such as a reactive ion etching process may be performed on the third capping film 172 and the first sacrificial film 170 using the photoresist pattern 174p as an etch mask to expose the second capping film pattern 134a, and then a wet etching process using HF may be performed to form the first sacrificial film pattern 170p by partially removing a portion of the first sacrificial film 170 disposed under the third capping film pattern 172p. In the wet etching, the upper surface of the second capping film pattern 134a may be recessed as described above.

In the process of removing at least a portion of the first sacrificial film 170 to form the first sacrificial film patterns 170p, a second opening 170t may be formed. The second opening 170t may have a second sidewall exposing each of the third capping film pattern 172p and the first sacrificial film pattern 170p and a second bottom surface exposing the upper surface of the second capping film pattern 134a. The upper surface of the second capping film pattern 134a may have a curved upper surface. The curved upper surface covers both the upper surface of the second gate structure 142 and gradually increases in height from the overlapping section with the upper surface of the second gate structure 142 towards a lower end of the first sacrificial film pattern 170p.

Referring to FIGS. 22 and 23, a second sacrificial film 178 surrounding the first sacrificial film patterns 170p and the third capping film patterns 172p may be formed on the second capping film pattern 134a. The second sacrificial film 178 may fill the second opening 170t while being disposed on the upper surface of the second capping film pattern 134a. The second sacrificial film 178 may include or may be formed of, for example, SOH (Spin-On-Hardmask). The second sacrificial film 178 may include or may be formed of at least one of silicon nitride, silicon carbide, and silicon oxynitride.

Referring to FIG. 24 and FIG. 25, after forming the second sacrificial film 178, a portion of the second sacrificial film 178 and the third capping film patterns 172p may be removed so that an upper surface of the second sacrificial film 178 and an upper surface of each of the first sacrificial film patterns 170p are coplanar with each other. For example, a chemical mechanical planarization (CMP) may be carried out such that the upper surface of the second sacrificial film 178 and the upper surface of each of the first sacrificial film patterns 170p are coplanar with each other. However, the present disclosure is not limited thereto.

Referring to FIG. 26 and FIG. 27, each of the first sacrificial film patterns 170p may be removed to form a third opening 178t1 having a third sidewall exposing the second sacrificial film 178 and a third bottom surface exposing an upper surface of the second capping film pattern 134a. A depth T4 of the third opening 178t1 may be about 1000 Å. However, the present disclosure is not limited thereto. A width of the third opening 178t1 may be substantially the same as that of each of the peripheral contact plugs (195b and 195c of FIGS. 4 and 5).

Referring to FIG. 28 and FIG. 29, a fourth opening 178t2 having a fourth sidewall aligned, in a vertical direction, with the third sidewall of the third opening 178t1, and extending into the bit-line structure 140 may be formed. The vertical direction may correspond to the fourth direction D4 which is perpendicular to the upper surface of the substrate 100. Referring to FIG. 28, in an area where the first peripheral contact plug is to be formed, the fourth opening 178t2 may extend downwardly from the third opening 178t1 by a predetermined depth T5.

Referring to FIG. 29, in an area where the second peripheral contact plug is to be formed, the fourth opening 178t2 extending into a portion of the substrate 100 and having a fourth bottom surface partially exposing an inside of the substrate 100 may be defined on each of both opposite sides of each of the peripheral gate structures 142. In an area where the second peripheral contact plug is to be formed, the fourth opening 178t2 may extend from the third opening 178t1 by the depth T5 of about 1500 Å. However, the present disclosure is not limited thereto.

Referring to FIG. 30 and FIG. 31, the second sacrificial film 178 may be removed. Subsequently, the third and fourth openings 178t1 and 178t2 may be filled with metal patterns, and thus the peripheral contact plugs 195b and 195c may be formed in the peripheral area II to manufacture the semiconductor memory device as shown in FIGS. 1 to 6.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A semiconductor memory device comprising:
a substrate including a cell area and a peripheral area adjacent to the cell area;
a first interlayer insulating film disposed on the substrate;
a first capping film disposed on the first interlayer insulating film;
a cell gate structure buried in the cell area of the substrate;
a first bit-line structure disposed on the cell area of the substrate;
a peripheral gate structure disposed on the peripheral area of the substrate; and
a peripheral contact plug disposed at the peripheral area and extending through the first capping film and the first interlayer insulating film,
wherein the first capping film includes a first portion overlapping an upper surface of the peripheral gate structure and a second portion adjacent to a sidewall of the peripheral contact plug, an upper surface of the first portion being lower than an upper surface of the second portion,
wherein the peripheral contact plug includes a first plug portion contacting the first interlayer insulating film, and a second plug portion contacting the first capping film, and
wherein a width of the first plug portion is equal to a width of the second plug portion.

2. The semiconductor memory device of claim 1,
wherein the peripheral contact plug further includes a third plug portion extending into the substrate and contacting the substrate, and
wherein the width of the second plug portion is equal to a width of the third plug portion.

3. The semiconductor memory device of claim 2,
wherein a width at a vertical median level of the first plug portion is greater than each of the width of the second plug portion and the width of the third plug portion.

4. The semiconductor memory device of claim 1, further comprising:
a second interlayer insulating film disposed on the first capping film; and
a connection wiring disposed in the second interlayer insulating film and connected to the peripheral contact plug.

5. The semiconductor memory device of claim 4,
wherein a width of the connection wiring is greater than or equal to each of the width of the first plug portion and the width of the second plug portion.

6. The semiconductor memory device of claim 4,
wherein a width of the connection wiring is smaller than each of the width of the first plug portion and the width of the second plug portion.

7. The semiconductor memory device of claim 1,
wherein the first capping film has a curved upper surface with an increasing height from the upper surface of the first portion of the first capping film toward the upper surface of the second portion of the first capping film.

8. The semiconductor memory device of claim 1,
wherein each of a sidewall of the first plug portion and a sidewall of the second plug portion extends in a vertical direction that is perpendicular to an upper surface of the substrate.

9. The semiconductor memory device of claim 1, further comprising:
a second bit-line structure disposed on the cell area of the substrate and adjacent to the first bit-line structure; and
a cell contact plug disposed in a space between the first and second bit-line structures and connected to a capacitor.

10. A semiconductor memory device comprising:
a substrate including a cell area and a peripheral area adjacent to the cell area;
a first interlayer insulating film disposed on the substrate;
a first capping film disposed on the first interlayer insulating film;
a cell gate structure buried in the cell area of the substrate;
a bit-line structure disposed on the cell area of the substrate;
a peripheral gate structure disposed on the peripheral area of the substrate; and
a peripheral contact plug disposed at the peripheral area and extending through the first capping film and the first interlayer insulating film into the substrate,
wherein a lower end of the peripheral contact plug is buried in the substrate, and
wherein a height of an upper surface of the first capping film pattern at a first position closest to a center of an upper surface of the peripheral gate structure is smaller than a height of the upper surface of the first capping film pattern at a second position closest to an upper end of the peripheral contact plug.

11. The semiconductor memory device of claim 10,
wherein the first capping film has a curved upper surface with an increasing height from the upper surface of the first capping film at the first position toward the upper surface of the first capping film at the second position.

12. The semiconductor memory device of claim 10,
wherein the peripheral contact plug includes a first plug portion contacting the first interlayer insulating film, a second plug portion contacting the first capping film, and a third plug portion containing the substrate, and
wherein a width of the third plug portion is equal to a width of the second plug portion.

13. The semiconductor memory device of claim 12,
wherein the width of the first plug portion is greater than each of the width of the second plug portion and a width of the third plug portion.

14. The semiconductor memory device of claim 12, further comprising:
a second interlayer insulating film disposed on the first capping film; and
a connection wiring disposed in the second interlayer insulating film and connected to the peripheral contact plug,
wherein a width of the connection wiring is greater than or equal to each of the width of the first plug portion and the width of the second plug portion.

15. A method of manufacturing a semiconductor memory device, the method comprising:
providing a substrate including a cell area and a peripheral area adjacent to the cell area;
forming a cell gate structure buried in the cell area of the substrate;
forming a bit-line structure disposed on the cell area of the substrate;
forming a pair of peripheral gate structures disposed on the peripheral area of the substrate;
forming a first interlayer insulating film in a space between the pair of peripheral gate structures;
forming a first capping film on the first interlayer insulating film, wherein the first capping film covers the bit-line structure and the pair of peripheral gate structures;
sequentially forming a first sacrificial film, a second capping film and a photoresist film on the first capping film;
patterning the photoresist film to form a photoresist pattern with a first opening exposing the second capping film;
etching a portion of the second capping film using the photoresist pattern to form a second capping film pattern;
etching a portion of the first sacrificial film using the photoresist pattern to form a first sacrificial film pattern;
forming a second sacrificial film on the first capping film, wherein the second sacrificial film surrounds the second capping film pattern and the first sacrificial film pattern;
removing the first sacrificial film pattern to form a second opening exposing an upper surface of the first capping film;
forming a third opening in the first interlayer insulating film between the pair of peripheral gate structures using the second opening, wherein an inner sidewall of the third opening is vertically aligned with an inner sidewall of the second opening, and wherein a bottom surface of the third opening is lower than an upper surface of the substrate; and
forming a peripheral contact plug in the second and third openings that are connected with each other.

16. The method of claim 15,
wherein the forming of the first sacrificial film pattern includes forming a recess at the upper surface of the first capping film, and
wherein the recess corresponds to a curved upper surface of the first capping film, the curved upper surface having an increasing height from an upper surface of the first capping film at a first position closest to a center of an upper surface of one of the pair of peripheral gate structures toward the upper surface of the first capping film at a second position closest to the peripheral contact plug.

17. The method of claim 15,
wherein a width of the first sacrificial film pattern is smaller than a width of the second capping film pattern.

18. The method of claim 15, further comprising:
removing, after the forming of the second sacrificial film, a portion of the second sacrificial film and the second capping film pattern so that an upper surface of the second sacrificial film and an upper surface of the first sacrificial film pattern are coplanar with each other.

19. The method of claim 15,
wherein a width of the first sacrificial film pattern is equal to a width of the peripheral contact plug.

20. The method of claim 15,
wherein a width of the second opening is equal to a width of the peripheral contact plug.
